(19) United States
(12) Patent Application Publication
(10) Pub. No.: US 2025/0115993 A1
(43) Pub. Date: Apr. 10, 2025

(54) SUBSTRATE PROCESSING APPARATUS, CLEANING METHOD, METHOD OF MANUFACTURING SEMICONDUCTOR DEVICE, AND RECORDING MEDIUM

(71) Applicant: Kokusai Electric Corporation, Tokyo (JP)

(72) Inventors: Takeo HANASHIMA, Toyama-shi (JP); Shinya EBATA, Toyama-shi (JP); Keigo NISHIDA, Toyama-shi (JP)

(73) Assignee: Kokusai Electric Corporation, Tokyo (JP)

(21) Appl. No.: 18/891,314

(22) Filed: Sep. 20, 2024

(30) Foreign Application Priority Data
Oct. 5, 2023 (JP) 2023-173872

(51) Int. Cl. C23C 16/44; C23C 16/52

(52) U.S. Cl. CPC C23C 16/4405; C23C 16/4412; C23C 16/52

(57) ABSTRACT

There is provided a technique that includes: a process container; an exhaust pipe connected to the process container; an opening/closing valve installed at the exhaust pipe; a pressure regulating valve installed at the exhaust pipe; a first supply system supplying one of a cleaning gas and an additive gas, having a molecular structure different from that of the cleaning gas, into the exhaust pipe through a gas supply pipe connected to an upstream of at least one of the opening/closing and pressure regulating valves; a second supply system supplying the other of the cleaning gas and the additive gas into the process container; and a controller capable of controlling the opening/closing valve, the pressure regulating valve, and the first and second supply systems so as to perform a cleaning process of simultaneously supplying the cleaning gas and the additive gas while the opening/closing and pressure regulating valves are opened.

### CROSS-REFERENCE TO RELATED APPLICATION

This application is based upon and claims the benefit of priority from Japanese Patent Application No. 2023-173872, filed on Oct. 5, 2023, the entire contents of which are incorporated herein by reference.

### TECHNICAL FIELD

The present disclosure relates to a substrate processing apparatus, a method of cleaning, a method of manufacturing a semiconductor device, and a recording medium.

### BACKGROUND

When performing a film-forming process on a substrate in a process chamber, a film-forming gas or its by-products may adhere as deposits to an opening/closing valve installed at an exhaust pipe. Since these deposits may hinder the operation of the opening/closing valve, etc., or become particles to affect the film-forming process, a cleaning process is sometimes performed to remove the deposits by supplying a cleaning gas into the exhaust pipe.

### SUMMARY

Some embodiments of the present disclosure provide a technique capable of efficiently removing deposits adhered to an opening/closing valve and the like installed at an exhaust pipe, when performing a cleaning process by using a cleaning gas.

According to embodiments of the present disclosure, there is provided a technique that includes: a process container; an exhaust pipe that is connected to the process container; an opening/closing valve that is installed at the exhaust pipe; a pressure regulating valve that is installed at the exhaust pipe; a first supply system configured to supply one of a cleaning gas and an additive gas, which has a molecular structure different from a molecular structure of the cleaning gas, into the exhaust pipe through a gas supply pipe connected to a position on the exhaust pipe at an upstream of at least one selected from the group of the opening/closing valve and the pressure regulating valve; a second supply system configured to supply the other of the cleaning gas and the additive gas into the process container; and a controller configured to be capable of controlling the opening/closing valve, the pressure regulating valve, the first supply system, and the second supply system so as to perform a cleaning process of simultaneously performing the supply of the cleaning gas and the additive gas in a state where the opening/closing valve and the pressure regulating valve are opened.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in embodiments of the present disclosure, in which a portion of the process furnace is shown in a vertical cross-sectional view.

FIG. 2 is a schematic configuration diagram of the vertical process furnace of the substrate processing apparatus suitably used in the embodiments of the present disclosure, in which a portion of the process furnace is shown in a cross-sectional view taken along line A-A in FIG. 1.

FIG. 3 is a schematic configuration diagram of a controller of the substrate processing apparatus suitably used in the embodiments of the present disclosure, in which a control system of the controller is shown in a block diagram.

FIG. 4 is a schematic partially-enlarged view of a substrate processing apparatus in a second modification of the present disclosure, in which gases supplied are shown.

FIG. 5 is a schematic partially-enlarged view of a substrate processing apparatus in a third modification of the present disclosure, in which gases supplied are shown.

FIG. 6 is a schematic partially-enlarged view of a substrate processing apparatus in a fourth modification of the present disclosure, in which gases supplied are shown.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### One Embodiment of the Present Disclosure

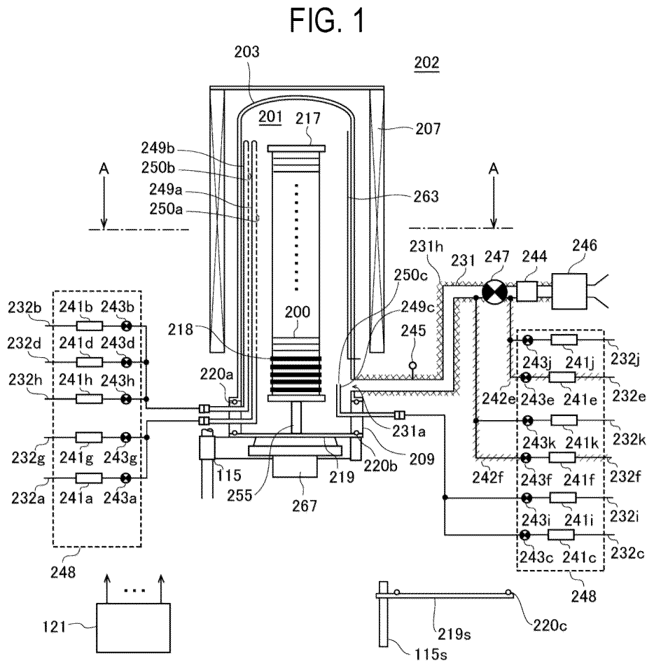

Embodiment of the present disclosure are described mainly with reference to FIGS. 1 to 3. The drawings used in the following description are schematic, and dimensional relationships, proportions, and the like of various elements shown in the drawings may not correspond to the actual ones. Further, the dimensional relationships, proportions, and the like of various elements may not match among the plurality of figures.

### (1) Configuration of Substrate Processing Apparatus

As shown in FIG. 1, a process furnace 202 includes a heater 207 as a temperature regulator (a heating part). The heater 207 is in a cylindrical shape and is supported by a support plate so as to be vertically installed. The heater 207 also functions as an activator (an exciter) that thermally activates (excites) a gas.

A reaction tube 203 is disposed inside the heater 207 to be concentric with the heater 207. The reaction tube 203 is made of, for example, a heat resistant material such as quartz (SiO₂), silicon carbide (SiC), or the like and is in a cylindrical shape with its upper end closed and its lower end opened. A manifold 209 is disposed to be concentric with the reaction tube 203 below the reaction tube 203. The manifold 209 is made of, for example, a metal-containing material such as stainless steel (SUS), etc., and is formed in a cylindrical shape with its upper and lower ends opened. The upper end of the manifold 209 engages with the lower end of the reaction tube 203 via an O-ring 220a so as to support the reaction tube 203. A process container (reaction container) mainly includes the reaction tube 203 and the manifold 209. A process chamber 201 is formed in a hollow cylindrical portion of the process container. The process chamber 201 is configured to be capable of accommodating wafers 200 as substrates. Processing on the wafers 200 is performed in the process chamber 201.

In the process chamber 201, nozzles 249a to 249c as first to third suppliers are installed to penetrate through a sidewall of the manifold 209. The nozzles 249a to 249c are also referred to as first to third nozzles, respectively. The nozzles 249a to 249c are made of, for example, a heat resistant material such as quartz, SiC, or the like. Gas supply pipes 232a to 232c are connected to the nozzles 249a to 249c, respectively. Compared to the nozzles 249a and 249b, the nozzle 249c is disposed to be closer to an exhaust port 231a, which is described later.

On the gas supply pipes 232a to 232c, mass flow controllers (MFCs) 241a to 241c, which are flow rate controllers (flow rate control parts), and valves 243a to 243c, which are opening/closing valves, are respectively installed sequentially from an upstream of a gas flow. A gas supply pipe 232g is connected to the gas supply pipe 232a at a downstream of the valve 243a. Each of gas supply pipes 232d and 232h is connected to the gas supply pipe 232b at a downstream of the valve 243b. A gas supply pipe 232i is connected to the gas supply pipe 232c at a downstream of the valves 243c. On the gas supply pipes 232d and 232g to 232i, MFCs 241d and 241g to 241i and valves 243d and 243g to 243i are respectively installed sequentially from an upstream of a gas flow. The gas supply pipes 232a to 232i are made of, for example, a metal material such as SUS, etc.

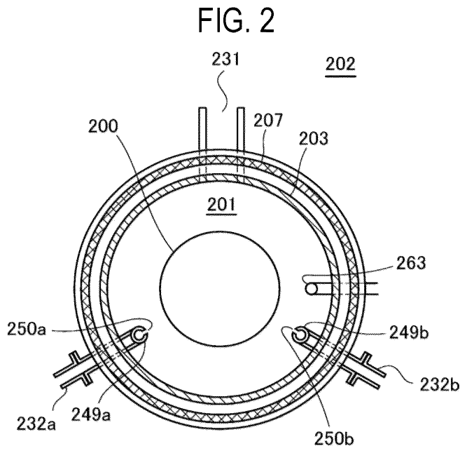

As shown in FIG. 2, each of the nozzles 249a and 249b is installed so as to extend upward from a lower portion of an inner wall of the reaction tube 203 to an upper portion thereof, that is, along an arrangement direction of the wafers 200. That is, each of the nozzles 249a and 249b is installed in a region, which horizontally surrounds a wafer arrangement region where the wafers 200 are arranged, at a side of the wafer arrangement region, so as to be aligned along the wafer arrangement region. Gas supply holes 250a and 250b for supplying a gas are formed on a side of the nozzles 249a and 249b, respectively. The gas supply holes 250a and 250b are formed in plural from a lower portion of the reaction tube 203 to an upper portion thereof.

The nozzle 249c is installed so as to extend upward in the arrangement direction of the wafers 200 from the lower portion of the inner wall of the reaction tube 203 to the vicinity of the exhaust port 231a which is described later. A gas supply hole 250c for supplying a gas is formed in a leading end of the nozzle 249c.

The exhaust port 231a for exhausting an internal atmosphere of the process chamber 201 is installed at a lower portion of a sidewall of the reaction tube 203, and an exhaust pipe 231 is connected to the exhaust port 231a. The exhaust pipe 231 is installed with a pressure sensor 245 as a pressure detector (pressure detection part) for detecting an internal pressure of the process chamber 201, a GV (Gate Valve) 247 as an opening/closing valve, and an APC (Auto Pressure Controller) valve 244 as a pressure regulating valve (pressure regulating part) sequentially from an upstream. The APC valve 244 is formed of, for example, a butterfly valve. In addition, an exhaust pipe temperature sensor (not shown) is attached at an upstream of the GV 247. The exhaust pipe temperature sensor may be formed of a known temperature sensor such as a thermocouple, etc. A vacuum pump 246 as a vacuum exhauster is connected to the exhaust pipe 231 via the pressure sensor 245, the GV 247, and the APC valve 244. The GV 247 and the APC valve 244 are configured to perform or stop a vacuum exhaust in the process chamber 201 by opening or closing the valve while the vacuum pump 246 is actuated. The APC valve 244 is also configured to regulate the internal pressure of the process chamber 201 by adjusting an opening degree of the valve based on pressure information detected by the pressure sensor 245 while the vacuum pump 246 is actuated. An exhaust system mainly includes the exhaust pipe 231, the APC valve 244, the GV 247, and the pressure sensor 245. The exhaust system may include the vacuum pump 246.

As the opening/closing valve, a valve suitable for opening/closing operation (on/off operation), such as a ball valve or the like, may be mainly used in addition to the GV. However, this does not exclude the use of a valve whose valve body capable of being controlled to be in an intermediate opening degree, as the opening/closing valve. In addition, as the pressure regulating valve, a valve suitable for flow rate regulating operation, such as a globe valve or the like, may be mainly used in addition to the butterfly valve. As the pressure regulating valve, a valve whose valve body capable of being controlled to be in an intermediate opening degree may be used.

A gas supply pipe 232e is connected between the GV 247 and the APC valve 244 of the exhaust pipe 231. A gas supply pipe 232f is connected to the upstream of the GV 247 of the exhaust pipe 231. The gas supply pipes 232e and 232f are installed with MFCs 241e and 241f and valves 243e and 243f, respectively, sequentially from an upstream of a gas flow. A gas supply pipe 232j is connected to the gas supply pipe 232e at a downstream of the valve 243e. The gas supply pipe 232j is installed with a MFC 241j and a valve 243j sequentially from an upstream of a gas flow. A gas supply pipe 232k is connected to the gas supply pipe 232f at a downstream of the valve 243f. The gas supply pipe 232k is installed with a MFC 241k and a valve 243k sequentially from an upstream of a gas flow. In the embodiments, gas supply pipe coolers 242e and 242f as gas supply pipe cooling devices are attached to an outer periphery of the gas supply pipes 232e and 232f, respectively. An exhaust pipe heater 231h is attached to an outer periphery of the exhaust pipe 231. In addition, gas supply pipe temperature sensors (not shown) are attached to an upstream of the MFCs 241e and 241f of the gas supply pipes 232e and 232f, respectively. The gas supply pipe temperature sensors may be composed of known temperature sensors such as thermocouples, etc.

A precursor (precursor gas) as a film-forming gas is supplied from the gas supply pipe 232a into the process chamber 201 via the MFC 241a, the valve 243a, and the nozzle 249a. The precursor gas is a gaseous precursor, for example, a gas obtained by vaporizing a precursor that is in a liquid state under room temperature and pressure, or a precursor that is in a gaseous state under room temperature and pressure, etc.

A first reaction gas as a film-forming gas is supplied from the gas supply pipe 232b into the process chamber 201 via the MFC 241b, the valve 243b, and the nozzle 249b. Further, in the embodiments, in a cleaning process, which is described later, the first reaction gas is also used as an additive gas.

An additive gas is supplied from the gas supply pipe 232c into the exhaust pipe 231 via the MFC 241c, the valve 243c, the nozzle 249c, and the process chamber 201.

A second reaction gas as a film-forming gas is supplied from the gas supply pipe 232d into the process chamber 201 via the MFC 241d, the valve 243d, the gas supply pipe 232b, and the nozzle 249b.

A cleaning gas is supplied from the gas supply pipe 232e into the exhaust pipe 231 via the MFC 241e and the valve 243e.

A cleaning gas is supplied from the gas supply pipe 232f into the exhaust pipe 231 via the MFC 241f and the valve 243f.

An inert gas is supplied from the gas supply pipes 232g and 232h into the process chamber 201 via the MFCs 241g and 241h, the valves 243g and 243h, the gas supply pipes 232a and 232b, and the nozzles 249a and 249b, respectively.

An inert gas is supplied from the gas supply pipe 232i into the exhaust pipe 231 via the MFC 241i, the valve 243i, the gas supply pipe 232c, and the nozzle 249c.

An inert gas is supplied from the gas supply pipes 232j and 232k into the exhaust pipe 231 via the MFCs 241j and 241k, the valves 243j and 243k, and the gas supply pipes 232e and 232f, respectively.

The inert gas acts as a purge gas, a carrier gas, a dilution gas, etc.

A precursor gas supply system mainly includes the gas supply pipe 232a, the MFC 241a, and the valve 243a. A first reaction gas supply system mainly includes the gas supply pipe 232b, the MFC 241b, and the valve 243b. When the first reaction gas is also used as an additive gas, the first reaction gas supply system further constitutes an additive gas supply system as a second supply system. The additive gas supply system mainly includes the gas supply pipe 232c, the MFC 241c, and the valve 243c. A second reaction gas supply system mainly includes the gas supply pipe 232d, the MFC 241d, and the valve 243d. A cleaning gas supply system (first supply system) mainly includes the gas supply pipe 232e, the MFC 241e, and the valve 243e. A cleaning gas supply system mainly includes the gas supply pipe 232f, the MFC 241f, and the valve 243f. An inert gas supply system mainly includes the rear gas supply pipes 232g to 232k, the MFCs 241g to 241k, and the valves 243g to 243k. Nozzles connected to the gas supply pipes included in the above-described various supply systems may be included in each of the supply systems.

Any of or the entire above-described various supply systems may be configured as an integrated-type supply system 248 in which the valves 243a to 243k, the MFCs 241a to 241k, and so on are integrated. The integrated-type supply system 248 is connected to each of the gas supply pipes 232a to 232k, and is configured such that operations of supplying various materials (various gases) into the gas supply pipes 232a to 232k (that is, the opening/closing operations of the valves 243a to 243k, the flow-rate regulating operations by the MFCs 241a to 241k, and the like) are controlled by a controller 121 to be described later.

A seal cap 219 as a furnace opening lid capable of air-tightly closing a lower end opening of the manifold 209 is installed below the manifold 209. The seal cap 219 is made of a metal-containing material such as SUS or the like and is formed in a disc shape. An O-ring 220b as a seal making contact with the lower end of the manifold 209, is installed on an upper surface of the seal cap 219. A rotator 267 for rotating a boat 217, which is described later, is installed below the seal cap 219. A rotary shaft 255 of the rotator 267 is made of a metal-containing material such as SUS or the like and is connected to the boat 217 through the seal cap 219. The rotator 267 is configured to rotate the wafers 200 by rotating the boat 217. The seal cap 219 is configured to be vertically moved up and down by a boat elevator 115 as a lift installed outside the reaction tube 203. The boat elevator 115 is configured as a transporter (transport mechanism) which loads/unloads (transports) the wafers 200 into/out of the process chamber 201 by moving the seal cap 219 up and down.

A shutter 219s as a furnace opening lid capable of air-tightly closing the lower end opening of the manifold 209 via an O-ring 220c in a state where the seal cap 219 is lowered and the boat 217 is unloaded from the process chamber 201 is installed below the manifold 209. The shutter 219s is made of, for example, a metal-containing material such as SUS or the like and is formed in a disc shape. The opening/closing operation (such as lift operation, rotation operation, or the like) of the shutter 219s is controlled by a shutter opening/closing mechanism 115s.

The boat 217 as a substrate support is configured to support a plurality of wafers 200, for example, 25 to 200 wafers, in such a state that the wafers 200 are arranged in a horizontal posture and in multiple stages along a vertical direction with centers of the wafers 200 aligned with one another. That is, the boat 217 is configured to arrange the wafers 200 to be spaced apart from each other. The boat 217 is made of, for example, a heat resistant material such as quartz, SiC, or the like. At a lower portion of the boat 217, heat insulating plates 218 made of, for example, a heat resistant material such as quartz, SiC, or the like are supported in multiple stages.

A temperature sensor 263 as a temperature detector is installed in the reaction tube 203. Based on temperature information detected by the temperature sensor 263, a state of supplying electric power to the heater 207 is regulated such that an interior of the process chamber 201 achieves a desired temperature distribution. The temperature sensor 263 is installed along the inner wall of the reaction tube 203.

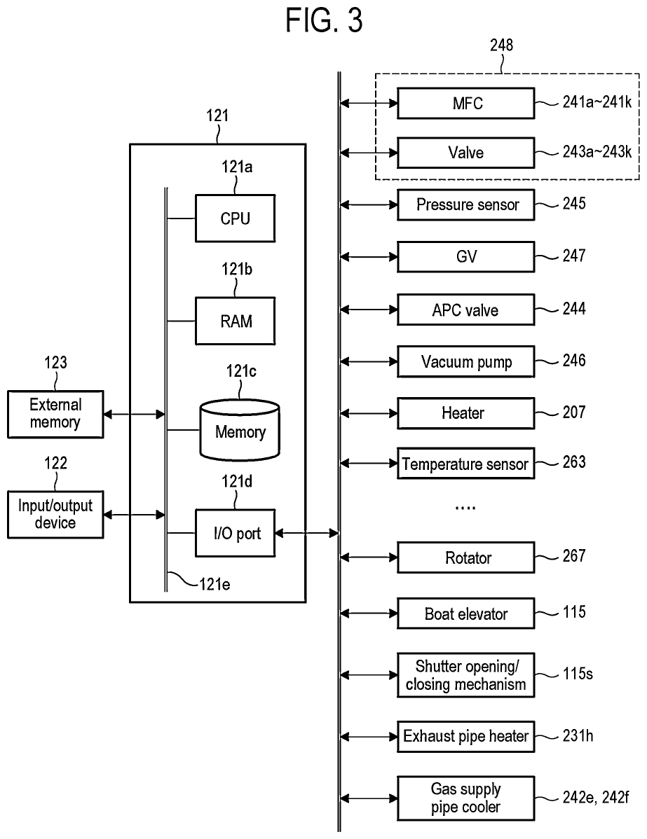

As shown in FIG. 3, a controller 121, which is a control part (control means), is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 formed of, e.g., a touch panel or the like, is connected to the controller 121. In addition, an external memory 123 may be connected to the controller 121. Further, the substrate processing apparatus may be configured to include one controller, or may be configured to include a plurality of controllers. That is, control for performing a processing sequence to be described later may be performed using one controller, or may be performed using a plurality of controllers. Further, the plurality of controllers may be configured as a control system by being connected to one another via a wired or wireless communication network, and the entire control system may perform control for performing the processing sequence to be described later. When the term “controller” is used in the present disclosure, it may include one controller, a plurality of controllers, or a control system configured by a plurality of controllers.

The memory 121c is configured by, for example, a flash memory, a hard disk drive (HDD), a solid state drive (SSD), or the like. A control program for controlling operations of the substrate processing apparatus, a process recipe in which procedures, conditions, etc. of substrate processing to be described later are written, etc. are readably recorded and stored in the memory 121c. The process recipe functions as a program that is combined to cause the controller 121 to execute each procedure of the substrate processing, which is described later, in the substrate processing apparatus to obtain a predetermined result. Hereinafter, the process recipe and the control program may be generally and simply referred to as a “program.” Furthermore, the process recipe may be simply referred to as a “recipe.” When the term “program” is used herein, it may refer to a case of including the recipe, a case of including the control program, or a case of including both the recipe and the control program. The RAM 121b is configured as a memory area (work area) in which programs, data, and the like read by the CPU 121a are temporarily stored.

The I/O port 121d is connected to the above-mentioned MFCs 241a to 241k, valves 243a to 243k, pressure sensor 245, APC valve 244, vacuum pump 246, temperature sensor 263, exhaust pipe temperature sensor, gas supply pipe temperature sensor, heater 207, exhaust pipe heater 231h, gas supply pipe coolers 242e and 242f, pipe rotator 267, boat elevator 115, shutter opening/closing mechanism 115s, and so on.

The CPU 121a is configured to read and execute the control program from the memory 121c. The CPU 121a is also configured to read the recipe from the memory 121c according to an input of an operation command and the like from the input/output device 122. The CPU 121a is configured to, according to contents of the recipe thus read, control the flow rate regulating operations of various kinds of materials (gases) by the MFCs 241a to 241k, the opening/closing operations of the valves 243a to 243k, the opening/closing operation of the APC valve 244, the pressure regulating operation performed by the APC valve 244 based on the pressure sensor 245, the startup and shutdown of the vacuum pump 246, the temperature regulating operation performed by the heater 207 based on the temperature sensor 263, the operation of rotating the boat 217 by the rotator 267 and adjusting the rotation speed of the boat 217, the operation of moving the boat 217 up and down by the boat elevator 115, the opening/closing operation of the shutter 219s by the shutter opening/closing mechanism 115s, and so on.

The controller 121 may be configured by installing, on the computer, the aforementioned program recorded and stored in the external memory 123. Examples of the external memory 123 may include a magnetic disk such as a HDD, an optical disc such as a CD, a magneto-optical disc such as a MO, a semiconductor memory such as a USB memory or a SSD, and the like. The memory 121c or the external memory 123 is configured as non-transitory computer-readable recording media. Hereinafter, the memory 121c and the external memory 123 may be collectively and simply referred to as a “recording medium”. When the term “recording medium” is used herein, it may refer to a case of including the memory 121c, a case of including the external memory 123, or a case of including both the memory 121c and the external memory 123. Furthermore, the program may be provided to the computer by using communication means such as the Internet or a dedicated line, instead of using the external memory 123.

### (2) Substrate Processing Process

As a process of manufacturing a semiconductor device using the above-described substrate processing apparatus, an example of a film-forming sequence for forming a film on a wafer 200 as a substrate is described. In the following description, the operations of the respective components constituting the substrate processing apparatus are controlled by the controller 121. This also applies to a cleaning process which is described later

A film-forming sequence in the present embodiments includes:
performing a cycle a predetermined number of times (n times, where n is an integer greater than or equal to 1), the cycle including non-simultaneously performing:
step S1 of supplying a precursor gas to the wafer 200 in the process container;
step S2 of supplying a first reaction gas to the wafer 200 in the process container; and
step S3 of supplying a second reaction gas to the wafer 200 in the process container.

In the following, an example in which a silicon oxynitride film (SiON film) is formed as a film on the wafer 200 is described.

### Wafer Charging and Boat Loading

After the boat 217 is charged with a plurality of wafers 200 (wafer charging), the boat 217 supporting the plurality of wafers 200 is lifted up by the boat elevator 115 and is loaded into the process chamber 201 (boat loading), as shown in FIG. 1.

### Pressure Regulation and Temperature Regulation

After the boat loading is completed, the interior of the process chamber 201, that is, a space where the wafers 200 are placed, is vacuum-exhausted by the vacuum pump 246 to reach a desired pressure. At this time, the APC valve 244 is feedback-controlled based on the pressure information measured by the pressure sensor 245. Further, the wafers 200 in the process chamber 201 are heated by the heater 207 so as to reach a desired processing temperature. Further, an inside of the exhaust pipe 231 is heated by the exhaust pipe heater 231h so as to reach a desired temperature. Herein, the inside of the exhaust pipe 231 is preferably heated to a temperature (for example, 150 to 250 degrees C.) that is capable of preventing a film-forming gas and its by-products exhausted into the exhaust pipe 231 during a film-forming process, which is described later, from being adhered to and deposited inside the exhaust pipe 231. Further, the rotation of the wafers 200 by the rotator 267 is started.

### Film-Forming Process

Thereafter, the following steps S1 to S3 are performed sequentially.

### Step S1

In this step, a precursor gas is supplied to the wafer 200 in the process chamber 201.

Specifically, the valve 243a is opened to allow the precursor gas to flow into the gas supply pipe 232a. A flow rate of the precursor gas is regulated by the MFC 241a, and the precursor gas is supplied into the process chamber 201 via the nozzle 249a and is exhausted through the exhaust port 231a.

A processing temperature when supplying the precursor gas in this step is, for example, 250 to 800 degrees C., specifically 400 to 700 degrees C. The same temperature condition may be used in other steps in the film-forming process.

The notation of a numerical range such as “250 to 800 degrees C.” in the present disclosure means that the lower limit value and the upper limit value are included in the range. Therefore, for example, “250 to 800 degrees C.” means “250 or higher and 800 or lower degrees C.” The same applies to other numerical ranges. In addition, the processing temperature in the present disclosure means a temperature of the wafer 200 or an internal temperature of the process chamber 201. These also apply to the following description.

By supplying, for example, a chlorosilane-based gas as the precursor gas to the wafer 200 under the above-mentioned condition, a silicon (Si)-containing layer containing chlorine (Cl) is formed as a first layer on a top surface of the wafer 200 serving as a base. In the present disclosure, the Si-containing layer containing Cl is also simply referred to as a “Si-containing layer.”

As the precursor gas, for example, a silane-based gas containing Si, serving as a main element constituting a film formed on the wafer 200, may be used. As the silane-based gas, for example, a gas containing Si and halogen, that is, a halosilane-based gas, may be used. Halogen includes chlorine (Cl), fluorine (F), bromine (Br), iodine (I), etc. As the halosilane-based gas, for example, the above-mentioned chlorosilane-based gas containing Si and Cl may be used.

Examples of the precursor gas may include chlorosilane-based gases such as a monochlorosilane (SiH₃Cl) gas, a dichlorosilane (SiH₂Cl₂) gas, a trichlorosilane (SiHCl₃) gas, a tetrachlorosilane (SiCl₄) gas, a hexachlorodisilane gas (Si₂Cl₆) gas, and an octachlorotrisilane (Si₃Cl₈) gas, etc., and gases containing Si and amino groups, i.e., aminosilane-based gases such as a tetrakis(dimethylamino)silane (Si[N(CH₃)₂]₄) gas and a tris(dimethylamino)silane (Si[N(CH₃)₂]₃H) gas, etc. One or more of these gases may be used as the precursor gas.

As the inert gas, for example, a nitrogen (N₂) gas or a rare gas such as an argon (Ar) gas, a helium (He) gas, a neon (Ne) gas, or a xenon (Xe) gas may be used. One or more of these gases may be used as the inert gas. This also applies to each step to be described later.

After the first layer is formed, the valve 243a is closed to stop the supply of the precursor gas into the process chamber 201. Then, the interior of the process chamber 201 is vacuum-exhausted to remove gases and the like remaining in the process chamber 201 from the interior of the process chamber 201. At this time, the valves 243g and 243h are opened to allow an inert gas to be supplied into the process chamber 201.

### Step S2

After step S1 is completed, a first reaction gas is supplied to the wafer 200 in the process chamber 201, i.e., the first layer formed on the wafer 200.

Specifically, the valve 243b is opened to allow the first reaction gas to flow into the gas supply pipe 232b. A flow rate of the first reaction gas is regulated by the MFC 241b, and the first reaction gas is supplied into the process chamber 201 via the nozzle 249b and is exhausted through the exhaust port 231a.

As the first reaction gas for the wafer 200, for example, a nitriding gas may be used. By supplying, for example, a nitrogen (N)- and H-containing gas as the nitriding gas, at least a portion of the first layer formed on the wafer 200 is modified (nitrided). This makes it possible to desorb Cl from the first layer and to introduce the N component contained in the N- and H-containing gas into the first layer. By modifying the first layer in this way, a silicon nitride layer (SiN layer) containing Si and N is formed as a second layer on the wafer 200.

As the first reaction gas, for example, a hydrogen nitride gas such as an ammonia (NH₃) gas, a diazene (N₂H₂) gas, a hydrazine (N₂H₄) gas, or a N₃H₈ gas may be used. One or more of these gases may be used as the first reaction gas.

After the second layer is formed, the valve 243b is closed to stop the supply of the first reaction gas into the process chamber 201. Then, the interior of the process chamber 201 is vacuum-exhausted to remove gaseous substances and the like remaining in the process chamber 201 from the interior of the process chamber 201. Then, gases and the like remaining in the process chamber 201 are removed from the interior of the process chamber 201 according to the same processing procedure as purging in step S1.

### Step S3

After step S2 is completed, a second reaction gas is supplied to the wafer 200 in the process chamber 201, i.e., the second layer formed on the wafer 200.

Specifically, the valve 243d is opened to allow the second reaction gas to flow into the gas supply pipe 232d. A flow rate of the second reaction gas is regulated by the MFC 241d, and the second reaction gas is supplied into the process chamber 201 via the nozzle 249b and is exhausted through the exhaust port 231a.

By supplying, for example, an O-containing gas as the second reaction gas to the wafer 200, at least a portion of the second layer formed on the wafer 200 is modified (oxidized). This makes it possible to desorb Cl from the second layer and to introduce the O component contained in the O-containing gas into the second layer. By modifying the second layer in this manner, a silicon oxynitride layer (SiON layer) containing Si, O, and N is formed as a third layer on the wafer 200.

As the second reaction gas, for example, an oxygen (O₂) gas, a nitrous oxide (N₂O) gas, a nitrogen monoxide (NO) gas, a nitrogen dioxide (NO₂) gas, a carbon monoxide (CO) gas, a carbon dioxide (CO₂) gas, etc. may be used. One or more of these gases may be used as the second reaction gas.

After the third layer is formed, the valve 243d is closed to stop the supply of the second reaction gas into the process chamber 201. Then, the interior of the process chamber 201 is vacuum-exhausted to remove gaseous substances and the like remaining in the process chamber 201 from the interior of the process chamber 201. Then, gases and the like remaining in the process chamber 201 are removed from the interior of the process chamber 201 according to the same processing procedure as the purging in step S1.

### Performing Predetermined Number of Times

By performing a cycle n times, the cycle including non-simultaneously, that is, without synchronization, performing the above-described steps S1 to S3 sequentially, a film with a predetermined thickness, for example, a SiON film with a predetermined thickness, may be formed on a base which is the surface of the wafer 200.

### After-Purge and Returning to Atmospheric Pressure

After the film-forming process is completed, an inert gas as a purge gas is supplied into the process chamber 201 from each of the gas supply pipes 232e and 232f and is exhausted through the exhaust port 231a. Thus, the interior of the process chamber 201 is purged (after-purge). After that, the internal atmosphere of the process chamber 201 is substituted with the inert gas and the internal pressure of the process chamber 201 is returned to the atmospheric pressure (returning to atmospheric pressure).

### Boat Unloading and Wafer Discharging

After that, the seal cap 219 is lowered, and the processed wafers 200 supported by the boat 217 are unloaded out of the reaction tube 203 (boat unloading). After the boat unloading, the lower end opening of the manifold 209 is sealed by the shutter 219s. The processed wafers 200 are discharged from the boat 217 (wafer discharging).

When the above-described substrate processing, i.e., the film-forming process, is performed, the film-forming gas, its by-products, and their reactants (e.g., silicon oxide and silicon oxynitride) may adhere to or deposit inside the exhaust system, for example, inside the exhaust pipe 231 or inside the GV 247 and the APC valve 244 installed in the exhaust pipe 231, etc. These adhering matters or deposits (hereinafter simply and collectively referred to as deposits) may adhere to valve bodies of the GV 247 and the APC valve 244 or their surroundings, hindering their operations or becoming particles to affect the film-forming process.

When the film-forming process is repeatedly performed with the deposits adhering to the inside of the exhaust system, the deposits may become stuck depending on the number of film-forming processes performed. The stuck deposits are difficult to be etched even when a cleaning gas is supplied to the inside of the exhaust system, thus making it difficult to remove them from the inside of the exhaust system.

In the present disclosure, after the above-described substrate processing process, a cleaning process to be described later is performed to remove the deposits adhered to the inside of the exhaust system.

### (3) Cleaning Process

As a process of manufacturing the semiconductor device using the above-described substrate processing apparatus, an example of cleaning for removing deposits adhered to the inside of the exhaust system, specifically, the inside of the GV 247 and the APC valve 244 installed at the exhaust pipe 231, is described.

A cleaning sequence in the present embodiments includes:
removing deposits adhered to at least one selected from the group of the GV 247 and the APC valve 244 by performing:
step a of supplying one of a cleaning gas and an additive gas, which exhibits a molecular structure different from a molecular structure of the cleaning gas, into the exhaust pipe 231, connected to the process container and installed with the GV 247 and the APC valve 244, through a gas supply pipe connected to a position at an upstream of at least one selected from the group of the GV 247 and the APC valve 244 in a state where the GV 247 and the APC valve 244 are opened; and
step b of supplying the other of the cleaning gas and the additive gas to the exhaust pipe 231 through the process container while performing step a.

In the following, an example of supplying the cleaning gas to the exhaust pipe 231 through the gas supply pipe 232e connected to a position at an upstream of the APC valve 244 and at a downstream of the GV 247, in other words, between the GV 247 and the APC valve 244, in step a, is described. In addition, an example of supplying the additive gas to the exhaust pipe 231 through the process chamber 201 in step b is described.

### Pressure Regulation and Temperature Regulation

After the wafer discharging is completed, the inside of the exhaust pipe 231 is vacuum-exhausted by the vacuum pump 246 to reach a desired pressure. At this time, an internal pressure of the exhaust pipe 231 is measured by the pressure sensor 245, and the APC valve 244 is feedback-controlled based on measured pressure information. At this time, the GV 247 is in an open state (left open). In addition, the exhaust pipe 231 is heated by the exhaust pipe heater 231h so that the inside of the exhaust pipe 231 achieves a desired processing temperature. At this time, a state of supplying electric power to the exhaust pipe heater 231h is feedback-controlled based on temperature information detected by the exhaust pipe temperature sensor so that the inside of the exhaust pipe 231 achieves a desired temperature distribution. In addition, the gas supply pipe 232e is cooled by the gas supply pipe cooler 242e so that an inside of the gas supply pipe 232e achieves a desired processing temperature. At this time, a state of supplying electric power to the gas supply pipe cooler 242e is feedback-controlled based on temperature information detected by the supply pipe temperature sensor so that the inside of the gas supply pipe 232e achieves a desired temperature distribution. The cleaning process may also be performed in a state where the boat 217 without the wafers 200 placed thereon is inserted into the reaction tube 203 and the lower end opening of the manifold 209 is sealed by the seal cap 219.

### Regulation of Opening Degree of APC Valve 244

The opening degree of the valve body of the APC valve 244 is regulated (controlled) to be smaller than a full opening degree. A full opening of the APC valve 244 means, for example, that when a butterfly valve is used as the APC valve 244, a surface of the valve body of the APC valve 244 is approximately parallel to an extension direction (a gas flow direction) of the exhaust pipe 231. In the embodiments, for example, the surface of the valve body of the APC valve 244 is regulated to a predetermined angle (for example, 45°) less than 90° with respect to the gas flow direction. A timing of the opening degree regulation of the APC valve 244 is not limited to after the pressure regulation and temperature regulation in the exhaust pipe 231, but may be started simultaneously with either the wafer discharging or the pressure regulation and temperature regulation in the exhaust pipe 231, or at a time point prior to these. The GV 247 is maintained in the open state.

### Cleaning Process

After that, the following steps a and b are executed simultaneously.

### Step a

In this step, a cleaning gas is supplied from the first supply system into the exhaust pipe 231.

Specifically, the valve 243e is opened to allow the cleaning gas to flow into the gas supply pipe 232e. A flow rate of the cleaning gas is regulated by the MFC 241e, and the cleaning gas is supplied into the exhaust pipe 231 through the gas supply pipe 232e (cleaning gas supply). At this time, at least one selected from the group of the valves 243j and 243k may be opened to allow an inert gas to be supplied into the exhaust pipe 231.

A process condition when supplying the cleaning gas in this step is exemplified as follows:
Internal temperature of exhaust pipe 231: 25 (room temperature) to 150 degrees C., specifically 50 to 100 degrees C.
Internal pressure of exhaust pipe 231: 30 to 40,000 Pa
Internal temperature of gas supply pipe 232e: 15 to 70 degrees C., specifically 30 to 50 degrees C.
Cleaning gas supply flow rate: 0.5 to 10 slm
Inert gas supply flow rate (for each gas supply pipe): 0 to 20 slm
Supply time of each gas: 5 to 300 minutes

The internal temperature of the gas supply pipe 232e is preferably lower than the internal temperature of the exhaust pipe 231. The internal temperature of the exhaust pipe 231 in this step is preferably lower than the internal temperature of the exhaust pipe 231 in the above-described film-forming process. Further, when the supply flow rate includes 0 slm, 0 slm refers to a case where no substance (gas) is supplied.

As the cleaning gas, for example, halogen-containing gases such as a silicon tetrachloride (SiCl₄) gas, a hydrogen chloride (HCl) gas, a boron trichloride (BCl₃) gas, a chlorine (Cl₂) gas, a fluorine (F₂) gas, a hydrogen fluoride (HF) gas, a silicon tetrafluoride (SiF₄) gas, a nitrogen trifluoride (NF₃) gas, a chlorine trifluoride (ClF₃) gas, a boron tribromide (BBr₃) gas, a silicon tetrabromide (SiBr₄) gas, and a bromine (Br₂) gas may be used. One or more of these gases may be used as the cleaning gas. By reacting the halogen-containing gas with the deposits adhered to the inside of the exhaust system, it is possible to etch (remove) the deposits.

As the cleaning gas, it is preferable to use a F-containing gas such as the F₂ gas or the HF gas among the above-mentioned halogen-containing gases, and it is more preferable to use the HF gas among the F-containing gases. By using the HF gas, it is possible to efficiently remove deposits containing oxide even under a low temperature condition.

### Step b

At the same time as the start of step a, an additive gas is supplied from the second supply system into the process chamber 201.

Specifically, the valve 243b is opened to allow the additive gas to flow into the gas supply pipe 232b. A flow rate of the additive gas is regulated by the MFC 241b, and the additive gas is supplied into the process chamber 201 via the nozzle 249b and is exhausted through the exhaust port 231a. At this time, the additive gas is supplied into the exhaust pipe 231 (additive gas supply). At this time, the valves 243g and 243h may be opened to allow an inert gas to be supplied into the process chamber 201 via the nozzles 249a and 249b, respectively.

A process condition when supplying the additive gas in this step is exemplified as follows:
Additive gas supply flow rate: 1 to 20 slm
Inert gas supply flow rate (for each gas supply pipe): 0 to 20 slm
Other process conditions may be the same as the process condition in step a.

As the additive gas, for example, a N- and H-containing gas such as an NH₃ gas, a N₂H₂ gas, a N₂H₄ gas, and a N₃H₈ gas may be used. The N- and H-containing gas is both a N-containing gas and a H-containing gas. One or more of these gases may be used as the additive gas.

As the additive gas, for example, H-containing gases such as a H₂ gas, a mixture of H₂ gas and O₂ gas, and a H₂O gas may be used as the additive gas. One or more of these gases may be used as the additive gas.

By using the above-mentioned additive gas, a reaction between the deposits (particularly the deposits containing oxide) and the cleaning gas (particularly the halogen-containing gas) is promoted, making it possible to improve an efficiency of removing the deposits. Further, the additive gas is a gas that does not substantially react with the deposits adhered to at least one selected from the group of the GV 247 and the APC valve 244 by itself.

In this embodiment, as the additive gas, it is preferable to use a gas exhibiting a same molecular structure as the first reaction gas used in the film-forming process.

By simultaneously executing steps a and b under the above-mentioned conditions, the cleaning gas and the additive gas are mixed in the exhaust pipe 231.

By executing steps a and b under the above-mentioned conditions, the deposits adhered to the inside (more specifically, each valve body and its surroundings) of at least one selected from the group of the GV 247 and the APC valve 244 (hereinafter sometimes simply referred to as the APC valve 244, etc.) are exposed to the cleaning gas and the additive gas, and thus are removed. Specifically, the cleaning gas supplied into the exhaust pipe 231 between the GV 247 and the APC valve 244 and the additive gas supplied into the process chamber 201 are mixed at the downstream of the GV 247. The mixed gas thus generated efficiently removes the deposits adhered to the inside of the APC valve 244, etc.

After a predetermined time is elapsed, the valve 243e is closed to stop the supply of the cleaning gas into the exhaust pipe 231. The valve 243b is closed to stop the supply of the additive gas into the process chamber 201. Then, the interior of the process chamber 201 is vacuum-exhausted to remove gaseous substances and particles (hereinafter, residual gases and the like) remaining in the process chamber 201 and the exhaust pipe 231. Then, the residual gases and the like in the process chamber 201 and the exhaust pipe 231 are removed (purged) from the interior of the process chamber 201 according to the same processing procedure as the purging in step S1.

### (4) Effects of the Present Embodiments

According to the present embodiments, one or more effects set forth below may be achieved.

(a) By simultaneously performing the supply of the cleaning gas and the additive gas to the APC valve 244, etc., an etching rate of the deposits adhered to the inside of the APC valve 244, etc. (particularly the valve body and its surroundings) may be increased as compared to a case of supplying the cleaning gas alone. That is, a removal efficiency may be improved. In addition, since it is possible to increase the etching rate, a supply amount of cleaning gas needed may be reduced.

By directly supplying the cleaning gas into the exhaust pipe 231 through the gas supply pipe 232e connected between the GV 247 and the APC valve 244, diffusion of the cleaning gas into the process chamber 201, which causes excessive etching of members in the process chamber 201 and affects an environment in the process chamber 201, may be prevented.

By supplying the additive gas into the exhaust pipe 231 through the process chamber 201, a gas flow from the process chamber 201 to the exhaust pipe 231 is formed, so that the mixture of the cleaning gas and the additive gas may be prevented from flowing back or diffusing into the process chamber 201. This may further reduce the possibility of etching damage occurring to the members in the process chamber 201.

By using a gas with the same molecular structure as the first reaction gas (film-forming gas) used in the film-forming process as the additive gas supplied through the process chamber 201, the first reaction gas supply system and the additive gas supply system serving as the second supply system may be configured with (i.e., shared by) a same gas supply system. This may simplify the configuration of the gas supply system.

(b) By supplying the cleaning gas directly from the gas supply pipe 232e connected to the exhaust pipe 231 into the exhaust pipe 231 without passing through the process chamber 201, the cleaning gas and the additive gas may be mixed in the exhaust pipe 231, not in the process chamber 201. This makes it possible to prevent excessive etching of the members in the process chamber 201 by the mixture of the cleaning gas and the additive gas. In addition, it is possible to more efficiently remove the deposits adhered to the inside of the APC valve 244, etc., without consuming the mixed gas as an etching gas in the process chamber 201 (i.e., without reducing an activity of the mixed gas as an etching gas in the process chamber 201).

(c) Since the gas supply pipe 232e is connected to the exhaust pipe 231 between the GV 247 and the APC valve 244, the deposits adhered to the inside of the APC valve 244, which is located at a downstream of a connection point of the gas supply pipe 232e, may be removed primarily over the deposits adhered to the inside of the GV 247. That is, by mixing the cleaning gas and the additive gas in the immediate vicinity of the upstream of the APC valve 244, an etching efficiency for the APC valve 244 may be maximized.

(d) The gas supply pipe 232e is connected to the exhaust pipe 231 between the GV 247 and the APC valve 244 and the GV 247 is installed at the upstream of the APC valve 244, so that the deposits adhered to the inside of the APC valve 244 may be removed primarily. This makes it possible to maintain a high degree of accuracy in the regulation of the opening degree of the APC valve 244 which needs to perform the regulation of the opening degree of the valve body with a higher accuracy than the GV 247. In addition, it is possible to prevent the valve body of the APC valve 244 from malfunctioning in opening/closing.

(e) By supplying the cleaning gas from the first supply system and the additive gas from the second supply system, it is possible to supply the cleaning gas to a position at the downstream of the GV 247 and at the upstream of the APC valve 244, which is closest to the APC valve 244 in the exhaust pipe 231, to generate the mixture of the cleaning gas and the additive gas. This may minimize an amount of the mixed gas that is adsorbed to other portions in the exhaust pipe 231 and reacts with other portions and/or other deposits adhered thereto, thereby improving the etching rate of the deposits adhered to the APC valve 244 (especially, preceding to the GV 247). In addition, a temperature change caused by the cleaning gas passing through the exhaust pipe 231 may be minimized, so that the cleaning gas may be directly supplied to the APC valve 244 at a suitable temperature at which an etching effect is obtained.

(f) In the cleaning process, the internal temperature of the gas supply pipe 232e is controlled to be lower than the internal temperature of the exhaust pipe 231, thereby improving the etching rate of the deposits adhered to the inside of the APC valve 244, etc. Specifically, when a gas (e.g., a HF gas) exhibiting a high etching rate in a low temperature range (e.g., 25 to 150 degrees C.) is used as the cleaning gas, the cleaning gas maintained at a low temperature may be supplied to the exhaust pipe 231 and the APC valve 244, etc., by supplying the cleaning gas into the exhaust pipe 231 from the gas supply pipe 232e, which is lower in temperature than the exhaust pipe 231. This may improve the etching rate of the deposits adhered to the inside of the APC valve 244, etc. That is, it is possible to obtain this effect by using, as the cleaning gas, a gas whose etching rate at the internal temperature of the gas supply pipe 232e, which is a different temperature from the internal temperature of the exhaust pipe 231 (in the embodiments, a temperature lower than the internal temperature of the exhaust pipe 231), is higher than the etching rate at the internal temperature of the exhaust pipe 231.

(g) In the cleaning process, heating of the gas supply pipe 232e is not performed, thereby suppressing a temperature rise of the cleaning gas supplied from the gas supply pipe 232e into the exhaust pipe 231. Since the gas supply pipe 232e in the embodiments is not equipped with a gas supply pipe heater, the gas supply pipe 232e is not heated. This makes it possible to suppress the temperature rise of the cleaning gas when the cleaning gas is supplied from the gas supply pipe 232e into the exhaust pipe 231. Therefore, for example, when a gas exhibiting a higher etching rate in a low temperature region is used as the cleaning gas, a decrease in the etching rate for the deposits adhered to the inside of the APC valve 244, etc. may be suppressed.

(h) The internal temperature of the exhaust pipe 231 in the cleaning process is controlled to be lower than the internal temperature of the exhaust pipe 231 in the film-forming process, thereby improving the etching rate for the deposits adhered to the inside of the APC valve 244, etc. Specifically, in the embodiments, the internal temperature of the exhaust pipe 231 in the film-forming process is set to a relatively high temperature (for example, 150 to 250 degrees C.) that is capable of preventing the film-forming gas and its by-products, exhausted into the exhaust pipe 231 as a result of performing the film-forming process, from being adhered to the inside of the exhaust pipe 231. On the other hand, in the cleaning process, when a gas exhibiting a higher etching rate in a low temperature region is used as the cleaning gas, the etching rate of the deposits is higher in a state where the cleaning gas is at a lower temperature than in a state where the cleaning gas is heated to the temperature of the exhaust pipe 231 in the film-forming process. That is, if the internal temperature of the exhaust pipe 231 in the cleaning process is maintained at the above-mentioned high temperature, the etching rate of the deposits may decrease. In the embodiments, the etching rate of the deposits adhered to the inside of the APC valve 244, etc. may be improved by making the internal temperature of the exhaust pipe 231 in the cleaning process be lower than the internal temperature of the exhaust pipe 231 in the film-forming process.

(i) In the cleaning process, the opening degree of the valve body of the APC valve 244 is controlled to be smaller than the full opening degree. This may increase, relative to the flow of the cleaning gas, an amount (flux) of cleaning gas per unit area of the valve body of the APC valve 244 that contacts (collides with) the valve body of the APC valve 244, thereby improving the efficiency of removal of the deposits adhered to the valve body of the APC valve 244.

### (5) Modifications

The cleaning process sequence in the present embodiments may be changed as in the following modifications. Unless otherwise stated, the processing procedure and process condition in each step of each modification may be the same as the processing procedure and process condition in each step of the above-described processing sequence. In addition, the configuration of the substrate processing apparatus in the embodiments may be changed as shown in the following modifications. Unless otherwise stated, the substrate processing apparatus used in each modification is configured in the same way as the substrate processing apparatus shown in FIG. 1, and elements that are substantially the same as those described in FIG. 1 are denoted by the same reference numerals, and the explanation thereof is omitted. These modifications may be combined in any way.

### First Modification

In step a of the cleaning process, the cleaning gas may be supplied to the exhaust pipe 231 through the gas supply pipe 232f connected to a position at an upstream of both the APC valve 244 and the GV 247. In this modification, the cleaning gas supply system as the first supply system includes the gas supply pipe 232f, the MFC 241f, and the valve 243f.

This modification may also obtain at least some of the effects described in the above-described embodiments. In addition, in this modification, it is possible to effectively remove the deposits adhered to both the GV 247 and the APC valve 244 by using the mixture of the cleaning gas and the additive gas. Further, by mixing the cleaning gas and the additive gas in the immediate vicinity of the upstream of the GV 247, the deposits adhered to the inside of the GV 247 may be removed primarily over the deposits adhered to the inside of the APC valve 244.

### Second Modification

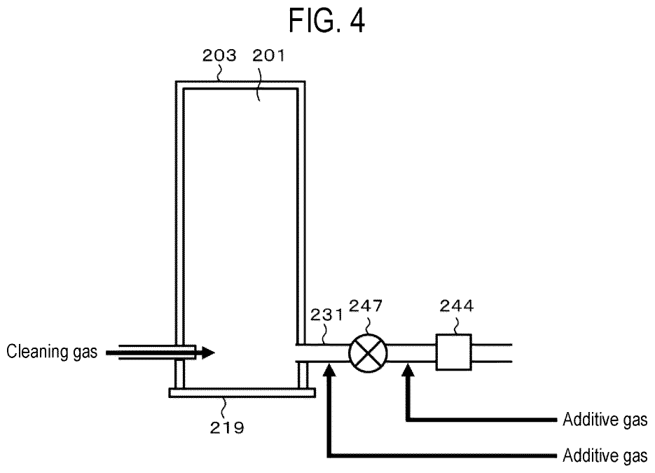

As shown in FIG. 4, in step a of the cleaning process, the first supply system may directly supply the additive gas into the exhaust pipe 231, and in step b, the second supply system may supply the cleaning gas to the exhaust pipe 231 through the process chamber 201.

Specifically, in step a, instead of the cleaning gas, the additive gas may be supplied to the exhaust pipe 231 through the gas supply pipe 232e connected between the GV 247 and the APC valve 244. In addition, it is also possible that, instead of the cleaning gas, the additive gas is supplied to the exhaust pipe 231 through the gas supply pipe 232f connected to a position at the upstream of both the APC valve 244 and the GV 247. In this modification, the first supply system configured to supply the additive gas includes at least one selected from the group of the gas supply pipes 232e and 232f. In addition, instead of the additive gas, the cleaning gas may be supplied into the process chamber 201 through the gas supply pipe 232b. In this modification, the second supply system configured to supply the cleaning gas includes the gas supply pipe 232b.

This modification may also obtain at least some of the effects described in the above-described embodiments. In addition, in this modification, the deposits adhered to the inside of both the GV 247 and the APC valve 244 may be removed by the cleaning gas. In addition, in step a, when the additive gas is supplied to the exhaust pipe 231 through the gas supply pipe 232e, the cleaning gas and the additive gas may be mixed in the immediate vicinity of the upstream of the APC valve 244. This makes it possible to remove the deposits adhered to the APC valve 244 primarily and more efficiently than the deposits adhered to the GV 247. On the other hand, when the additive gas is supplied to the exhaust pipe 231 through the gas supply pipe 232f, the cleaning gas and the additive gas may be mixed in the immediate vicinity of the upstream of the GV 247. This makes it possible to remove the deposits adhered to the GV 247 primarily and more efficiently than the deposits adhered to the APC valve 244. Moreover, by supplying the cleaning gas through the process chamber 201, deposits adhered to the process chamber 201 may also be removed at the same time.

### Third Modification

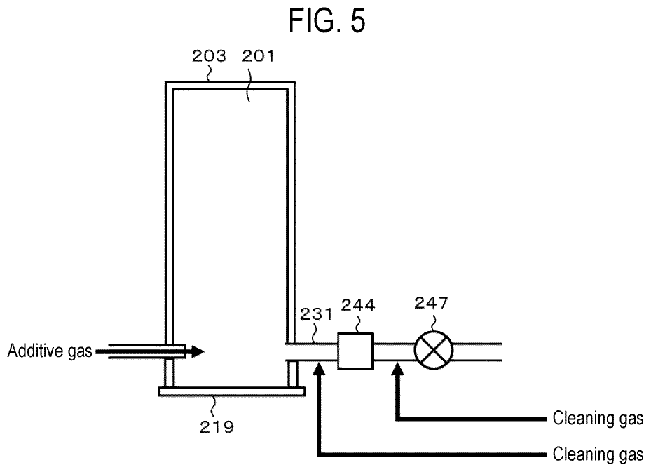

As shown in FIG. 5, the APC valve 244 and the GV 247 may be installed at the exhaust pipe 231 sequentially from the upstream.

Further, in step a, the first supply system may supply the cleaning gas to the exhaust pipe 231 through the gas supply pipe 232e connected between the GV 247 and the APC valve 244. It is also possible that the first supply system supplies the cleaning gas to the exhaust pipe 231 through the gas supply pipe 232f connected to a position at the upstream of both the APC valve 244 and the GV 247.

This modification may also obtain at least some of the effects described in the above-described embodiments. In addition, in this modification, in step a, when the cleaning gas is supplied to the exhaust pipe 231 through the gas supply pipe 232e, the cleaning gas and the additive gas may be mixed in the immediate vicinity of the upstream of the GV 247. This makes it possible to remove the deposits adhered to the GV 247 primarily and more efficiently than the deposits adhered to the APC valve 244. On the other hand, when the cleaning gas is supplied to the exhaust pipe 231 through the gas supply pipe 232f, the cleaning gas and the additive gas may be mixed in the immediate vicinity of the upstream of the APC valve 244. This makes it possible to remove the deposits adhered to the APC valve 244 primarily and more efficiently than the deposits adhered to the GV 247.

### Fourth Modification

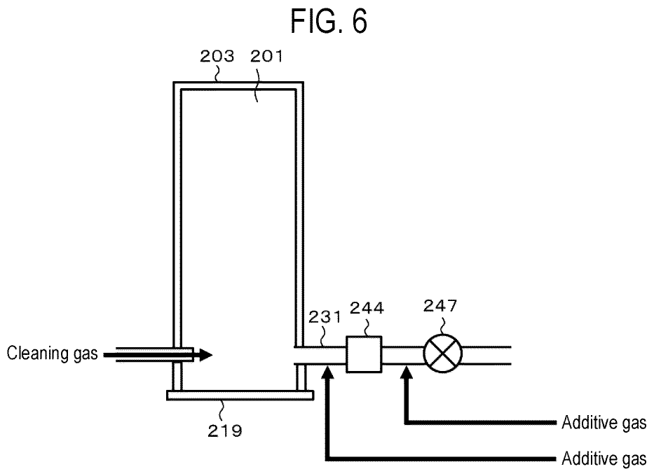

As shown in FIG. 6, the APC valve 244 and the GV 247 may be installed at the exhaust pipe 231 sequentially from the upstream.

Further, in step a, instead of the cleaning gas, the additive gas may be supplied to the exhaust pipe 231 through the gas supply pipe 232e connected between the GV 247 and the APC valve 244. In addition, it is also be possible that, instead of the cleaning gas, the additive gas is supplied to the exhaust pipe 231 through the gas supply pipe 232f connected to a position at the upstream of both the APC valve 244 and the GV 247. In this modification, as in the second modification, the first supply system configured to supply the additive gas includes at least one selected from the group of the gas supply pipes 232e and 232f. In addition, instead of the additive gas, the cleaning gas may be supplied into the process chamber 201 through the gas supply pipe 232b. In this modification, as in the second modification, the second supply system configured to supply the cleaning gas includes the gas supply pipe 232b.

This modification may also obtain at least some of the effects described in the above-described embodiments. In addition, in this modification, the deposits adhered to the inside of both the GV 247 and the APC valve 244 may be removed by the cleaning gas. In addition, in step a, when the additive gas is supplied to the exhaust pipe 231 through the gas supply pipe 232e, the cleaning gas and the additive gas may be mixed in the immediate vicinity of the upstream of the GV 247. This makes it possible to remove the deposits adhered to the GV 247 primarily and more efficiently than the deposits adhered to the APC valve 244. On the other hand, when the additive gas is supplied to the exhaust pipe 231 through the gas supply pipe 232f, the cleaning gas and the additive gas may be mixed in the immediate vicinity of the upstream of the APC valve 244. This makes it possible to remove the deposits adhered to the APC valve 244 primarily and more efficiently than the deposits adhered to the GV 247. Moreover, by supplying the cleaning gas through the process chamber 201, the deposits adhered to the process chamber 201 may also be removed at the same time.

### Other Embodiments of the Present Disclosure

The embodiments of the present disclosure are specifically described above. However, the present disclosure is not limited to the above-described embodiments, and various changes may be made without departing from the gist thereof.

In the above-described embodiments, in step b, a case where either the cleaning gas or the additive gas is supplied into the process chamber 201 through the gas supply pipe 232b and the nozzle 249b is described as an example. However, the present disclosure is not limited to such embodiments. For example, in step b, either the cleaning gas or the additive gas may be supplied into the process chamber 201 through the gas supply pipe 232c and the nozzle 249c. That is, the second supply system may include the gas supply pipe 232c and the nozzle 249c. In addition, the gas supply hole 250c formed at the lead end of the nozzle 249c is located below the wafer arrangement region and opens in the vicinity of the exhaust port 231a.

Even in this case, the same effects as in the above-described embodiments may be obtained. Further, by supplying the cleaning gas or the additive gas through the gas supply hole 250c located below the wafer arrangement region, impacts of these gases on the interior of the process chamber 201 (for example, occurrence of unexpected etching of members in the wafer arrangement region, such as the reaction tube 203, and impacts on the substrate processing due to a gas adhered to the members in the wafer arrangement region) may be reduced.

In addition, in the above-described embodiments, in step a, a case where either the cleaning gas or the additive gas is supplied into the exhaust pipe 231 from either the gas supply pipe 232e or the gas supply pipe 232f is described as an example. However, the present disclosure is not limited to such embodiments. For example, in step a, either the cleaning gas or the additive gas may be supplied into the exhaust pipe 231 from both the gas supply pipe 232e (first gas supply pipe) and the gas supply pipe 232f (second gas supply pipe). That is, the first supply system may be configured to include the gas supply pipe 232e and the gas supply pipe 232f. Even in this case, at least some of the effects described in the above-described embodiments may be obtained. In this embodiment, the cleaning gas and the additive gas may be mixed at a position in the immediate vicinity of the upstream of each of the GV 247 and the APC valve 244, thereby improving the effect of removal of the deposits adhered to both.

In addition, in the above-described embodiments, the cleaning process may be performed after performing several batches of the substrate processing process including the above-described film-forming process, or may be performed after performing each batch of the substrate processing process. Herein, one batch is defined as a single execution of the substrate processing process (for example, from boat loading to boat unloading).

In addition, in the above-described embodiments, a case where the gas supply pipe coolers 242e and 242f are attached to the outer peripheries of the gas supply pipes 232e and 232f, respectively, is described as an example. However, the present disclosure is not limited to such embodiments. For example, a gas supply pipe cooler may not be attached to at least one selected from the group of the outer peripheries of the gas supply pipes 232e and 232f. In addition, for example, a gas supply pipe heater may be attached to at least one selected from the group of the outer peripheries of the gas supply pipes 232e and 232f. Even in this case, the gas supply pipe heater may be controlled so as not to heat the gas supply pipe 232e in the cleaning process, thereby improving the effect of removal of the deposits adhered to the inside of the APC valve 244, etc.

In addition, in the above-described embodiments, the additive gas is described as a gas that promotes the reaction between the deposits and the cleaning gas, and is a gas that does not react with the deposits alone. This does not exclude use of the cleaning gas with an etching effect as the additive gas. If the gas is capable of promoting the etching effect of the deposits by being simultaneously supplied with the cleaning gas, a gas with the etching effect may also be used as the additive gas.

In addition, in the above-described embodiments, a case where the SiON film is formed on the surface of the wafer 200 in the film-forming process is described as an example. However, the present disclosure is not limited to such embodiments. For example, an oxide film (oxide) such as a silicon oxide film (SiO film), a silicon oxycarbide film (SiOC film), or a silicon oxycarbonitride film (SiOCN film) may be formed. In addition, for example, a nitride film (nitride) such as a silicon nitride film (SiN film), a silicon carbide film (SiC film), or a silicon carbonitride film (SiCN film) may be formed. In addition, a film (compound) containing an element other than Si may be formed. Even in these cases, the same effects as in the above-described embodiments may be obtained.

In addition, in the above-described embodiments, it is preferable to control the opening degree of the valve body of the APC valve 244 so as to change it with the passage of processing time in the cleaning process. This may promote the peeling off of the deposits adhered to a movable part of the valve body, thereby promoting the removal of the deposits.

In addition, in the above-described embodiments, each of the first supply system and the second supply system may be directly connected to the exhaust pipe 231. In other words, both a gas supply pipe for supplying the cleaning gas and a gas supply pipe for supplying the additive gas may be directly connected to the exhaust pipe 231. Connection positions of the first and second supply systems to the exhaust pipe 231 may be the same with respect to the GV 247 and the APC valve 244, or one of the first and second supply systems may be at the upstream of both the GV 247 and the APC valve 244, and the other may be between the GV 247 and the APC valve 244. This embodiment may also obtain at least some of the effects described in the above-described embodiments.

Recipes used in each process may be prepared individually according to processing contents and may be recorded and stored in the memory 121c via a telecommunication line or the external memory 123. Then, at the beginning of each process, the CPU 121a may adequately select an appropriate recipe from the recipes recorded and stored in the memory 121c according to the processing contents.

An example in which a film is formed using a batch-type substrate processing apparatus capable of processing a plurality of substrates at a time is described in the above-described embodiments. The present disclosure is not limited to the above-described embodiments, but may be suitably applied, for example, to a case where a film is formed using a single-wafer type substrate processing apparatus capable of processing a single substrate or several substrates at a time. In addition, an example in which a film is formed using a substrate processing apparatus equipped with a hot-wall type process furnace is described in the above-described embodiments. The present disclosure is not limited to the above-described embodiments, but may be suitably applied to a case where a film is formed using a substrate processing apparatus equipped with a cold-wall type process furnace.

Even in the case of using these substrate processing apparatuses, each process may be performed according to the same processing procedures and process conditions as those in the above-described embodiments and modifications, and the same effects as those of the above-described embodiments and modifications may be obtained.

The above-described embodiments and modifications may be used in proper combination. The processing procedures and process conditions used in this case may be the same as, for example, the processing procedures and process conditions in the above-described embodiments and modifications.

According to the present disclosure in some embodiments, it is possible to efficiently remove deposits adhered to an opening/closing valve and the like installed at an exhaust pipe when performing a cleaning process using a cleaning gas.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a process container;
an exhaust pipe that is connected to the process container;
an opening/closing valve that is installed at the exhaust pipe;
a pressure regulating valve that is installed at the exhaust pipe;
a first supply system configured to supply one of a cleaning gas and an additive gas, which has a molecular structure different from a molecular structure of the cleaning gas, into the exhaust pipe through a gas supply pipe connected to a position on the exhaust pipe at an upstream of at least one selected from the group of the opening/closing valve and the pressure regulating valve;
a second supply system configured to supply the other of the cleaning gas and the additive gas into the process container; and
a controller configured to be capable of controlling the opening/closing valve, the pressure regulating valve, the first supply system, and the second supply system so as to perform a cleaning process of simultaneously performing the supply of the cleaning gas and the supply of the additive gas in a state where the opening/closing valve and the pressure regulating valve are opened.

2. The substrate processing apparatus of claim 1, wherein, in the cleaning process, the cleaning gas and the additive gas are mixed in the exhaust pipe.

3. The substrate processing apparatus of claim 1, wherein, in the cleaning process, deposits adhered to at least one selected from the group of the opening/closing valve and the pressure regulating valve are removed by being exposed to the cleaning gas and the additive gas.

4. The substrate processing apparatus of claim 1, wherein the gas supply pipe is connected to the exhaust pipe between the opening/closing valve and the pressure regulating valve.

5. The substrate processing apparatus of claim 4, wherein the opening/closing valve is installed at an upstream of the pressure regulating valve.

6. The substrate processing apparatus of claim 4, wherein the first supply system supplies the cleaning gas and the second supply system supplies the additive gas.

7. The substrate processing apparatus of claim 6, wherein an etching rate of the cleaning gas is increased at a temperature different from a temperature of the exhaust pipe during the cleaning process.

8. The substrate processing apparatus of claim 4, wherein the first supply system supplies the additive gas and the second supply system supplies the cleaning gas.

9. The substrate processing apparatus of claim 1, wherein the gas supply pipe is connected to the exhaust pipe at an upstream of both the opening/closing valve and the pressure regulating valve.

10. The substrate processing apparatus of claim 9, wherein the opening/closing valve is installed at a downstream of the pressure regulating valve.

11. The substrate processing apparatus of claim 1, wherein the cleaning gas is a halogen-containing gas.

12. The substrate processing apparatus of claim 1, wherein the cleaning gas is a HF gas.

13. The substrate processing apparatus of claim 1, wherein the additive gas is a H-containing gas.

14. The substrate processing apparatus of claim 1, further comprising: an exhaust pipe heater configured to heat the exhaust pipe,
wherein the controller is configured to be capable of controlling the exhaust pipe heater so that a temperature of the gas supply pipe is lower than a temperature of the exhaust pipe in the cleaning process.

15. The substrate processing apparatus of claim 14, wherein heating of the gas supply pipe is not performed during the cleaning process.

16. The substrate processing apparatus of claim 14, wherein an etching rate of the cleaning gas for deposits adhered to at least one selected from the group of the opening/closing valve and the pressure regulating valve is higher when the cleaning gas is at a temperature lower than the temperature of the exhaust pipe than when the cleaning gas is at the temperature of the exhaust pipe.

17. The substrate processing apparatus of claim 1, wherein the controller is configured to be capable of controlling the pressure regulating valve so that an opening degree of the pressure regulating valve is less than a full opening degree during the cleaning process.

18. A cleaning method, comprising:
removing deposits adhered to at least one selected from the group of an opening/closing valve and a pressure regulating valve by performing:
(a) supplying one of a cleaning gas and an additive gas, which has a molecular structure different from a molecular structure of the cleaning gas, into an exhaust pipe, connected to a process container and installed with the opening/closing valve and the pressure regulating valve, through a gas supply pipe connected to a position on the exhaust pipe at an upstream of at least one selected from the group of the opening/closing valve and the pressure regulating valve in a state where the opening/closing valve and the pressure regulating valve are opened; and
(b) supplying the other of the cleaning gas and the additive gas into the exhaust pipe through the process container while performing (a).

19. A method of manufacturing a semiconductor device comprising the cleaning method of claim 18.

20. A non-transitory computer-readable recording medium storing a program that causes, by a computer, a substrate processing apparatus to perform a process comprising:
removing deposits adhered to at least one selected from the group of an opening/closing valve and a pressure regulating valve by performing:
(a) supplying one of a cleaning gas and an additive gas, which has a molecular structure different from a molecular structure of the cleaning gas, into an exhaust pipe, connected to a process container and installed with the opening/closing valve and the pressure regulating valve, through a gas supply pipe connected to a position on the exhaust pipe at an upstream of at least one selected from the group of the opening/closing valve and the pressure regulating valve in a state where the opening/closing valve and the pressure regulating valve are opened; and
(b) supplying the other of the cleaning gas and the additive gas into the exhaust pipe through the process container while performing (a).
